(19) United States
(12) Patent Application Publication
(10) Pub. No.: US 2014/0007811 A1
(43) Pub. Date: Jan. 9, 2014

(54) REPAIRING DEVICE FOR REPAIRING DISCONNECTED LINE

(71) Applicant: Wen-da Cheng, Shenzhen (CN)

(72) Inventor: Wen-da Cheng, Shenzhen (CN)

(73) Assignee: SHENZHEN CHINA STAR OPTOELECTRONICS TECHNOLOGY CO. LTD., Shenzhen, Guangdong (CN)

(21) Appl. No.: 13/702,585

(22) PCT Filed: Aug. 10, 2012
(86) PCT No.: PCT/CN12/79925

§ 371 Date: Dec. 7, 2012

(30) Foreign Application Priority Data
Jul. 9, 2012 (CN) 201220329608.5

(51) Int. Cl. C23C 16/44

(52) U.S. Cl. CPC C23C 16/44
USPC 118/715

(57) ABSTRACT

A repairing device for repairing disconnected lines, including a suction pipe, a number of blowing pipes surrounding the suction pipe and is noncoplanar with the suction pipe, each of the blowing pipes includes a blowing opening inclined toward the suction pipe; and a number of vapor coating pipes located between the suction pipe and the blowing pipes and being parallel with the suction pipe. With the configurations of the blowing pipes, the suction pipe, and the vapor coating pipes, the inert gas blown from the blowing pipes spreads from outside to inside, thus, molecules of the coating material ejected from the vapor coating pipes can be drawn close to the disconnected portion of the disconnected line, which avoids the short circuit caused by the spread molecules of the coating material in the present coating technology and increases the success rate of the coating operation.

### BACKGROUNDS

1. Technical Field

The present disclosure relates to technologies of liquid crystal panels and, particularly, to a repairing device for repairing disconnected lines on an array substrate.

2. Description of Related Art

Liquid Crystal Display (LCD) is a Flat Panel Display (FPD) that uses the characteristics of liquid crystal to display image. Compared to other types of display, LCD is thin and it requires lower driving voltage and lower power consumption, which makes it the mainstream product in the consumer goods market.

Liquid crystal panel is the main component of the LCD. The process for fabricating the liquid crystal panel mainly includes an earlier array fabricating process, a middle cell process, and a later module process. The earlier array fabricating process specifically includes: depositing a film layer on a substrate, coating photoresist on the film layer and carrying out exposing process, developing process, etching process, and photoresist stripping process to form scan lines, a semi-conductor layer, data lines, a protective layer, a transparent conductive layer, etc. After the earlier fabricating process is finished, the array substrate is detected to determine whether there are disconnected defects and/or short defects in data lines and scan lines. If there are disconnected defects and/or short defects in data lines or scan lines, a repairing device is used for repairing the disconnected and/or short data lines or scan lines. When there is disconnected defect, the repairing device at first removes the object covering two terminals of the disconnected line, such as the semi-conductor layer, and then coating the two terminals of the disconnected line to form a passageway.

When coating the two disconnected terminals of the disconnected line, the present repairing device ejects gas such as inert gas which does not react with the coating material in high temperature, which stabilizes the coating operation. Referring to FIG. 1, which is a schematic view showing the process of coating a disconnected portion of the disconnected line by a present repairing device. The repairing device is provided with an ejecting opening 101 arranged at the middle portion thereof for ejecting the inert gas, vapor coating openings 102 surrounding the ejecting opening 101 for ejecting coating material used for coating the disconnected line, and suction openings 103 surrounding the vapor coating opening 102 for sucking the inert gas.

In the above repairing device, gas channels are formed between the ejecting opening 101 and the suction openings 103, which causes the inert gas to spread, thereby causing the coating material to spread as well. This correspondingly increases the coating area. In this situation, the coating material may contact other lines of the liquid crystal panel surrounding the coating material and thus cause short circuit of the liquid crystal panel, referring to FIG. 2, FIG. 2 is a schematic view showing the short circuit caused by the increased coating area formed by the repairing device.

Therefore, how to prevent the short circuit of the liquid crystal panel caused by the increased coating area becomes a problem needs to be solved.

### SUMMARY

The present disclosure, in one aspect thereof, provides a repairing device for repairing disconnected lines, which improves the success rate of the coating operation.

The repairing device provided in the present disclosure includes a suction pipe, a number of blowing pipes, and a number of vapor coating pipes. The blowing pipes surround the suction pipe and are noncoplanar with the suction pipe, and each of the blowing pipes includes a blowing opening inclined toward the suction pipe. The vapor coating pipes are located between the suction pipe and the blowing pipes and are parallel with the suction pipe.

Preferably, the repairing device further includes a housing; the suction pipe, the blowing pipes, and the vapor coating pipes are all disposed on a lower surface of the housing, the suction pipe is perpendicular to the housing, and an angle formed between each blowing pipe and the lower surface of the housing ranges from 30 degrees to 60 degrees.

Preferably, each vapor coating pipe has a coating opening, the suction pipe has a suction opening, a distance between the coating opening and the housing is less than a distance between the suction opening and the housing, but greater than a distance between the blowing opening and the housing.

Preferably, the suction pipe has a suction opening, and an area surrounded by the blowing openings is less than or equal to the area of the suction opening.

Preferably, the repairing device further includes a controller connected to the blowing pipes for controlling the blowing openings of the blowing pipes to move towards the suction pipe.

Preferably, the angle formed between each blowing pipe and the lower surface of the housing is 45 degrees.

Preferably, the repairing device further includes a housing, the housing has a lower surface, the suction pipe is disposed in a center portion of the housing and runs through the lower surface; the vapor coating pipes and the blowing pipes are disposed inside the housing and run through the lower surface, and an angle formed between the suction pipe and the lower surface ranges from 30 degrees to 60 degrees.

Preferably, a first guiding ring is disposed on an edge of each blowing opening, each vapor coating pipe has a coating opening, and a second guiding ring is disposed on the edge of the coating opening.

Preferably, the angle formed between each blowing pipe and the lower surface of the housing is 45 degrees.

The present disclosure, in another aspect thereof, provides another repairing device for repairing disconnected lines, which includes a suction pipe, a number of blowing pipes, and a number of vapor coating pipes. The blowing pipes surround the suction pipe, each of the blowing pipes being inclined relative to the suction pipe and are noncoplanar with the suction pipe. The vapor coating pipes are located between the suction pipe and the blowing pipes.

Preferably, the repairing device further includes a housing, the suction pipe, the blowing pipes, and the vapor coating pipes are all disposed on a lower surface of the housing; the suction pipe is perpendicular to the housing, each blowing pipe has a blowing opening being inclined towards the suction pipe, and an angle formed between each blowing pipe and the lower surface of the housing ranges from 30 degrees to 60 degrees.

Preferably, each vapor coating pipe includes a coating opening, the suction pipe includes a suction opening, a distance between each coating opening and the housing is greater than a distance between the suction opening and the housing, but less than a distance between each blowing opening and the housing.

Preferably, the suction pipe includes a suction opening, and an area surrounded by the blowing openings is less than an area of the suction opening.

Preferably, the repairing device further includes a controller connected to the blowing pipes for controlling the blowing openings of the blowing pipes to move towards the suction pipe.

Preferably, the angle formed between each blowing pipe and the lower surface of the housing is 45 degrees.

Preferably, the repairing device further includes a housing having a lower surface, the suction pipe is disposed in a center portion of the housing and runs through the lower surface; the vapor coating pipes and the blowing pipes are disposed inside the housing and run through the lower surface of the housing; the blowing pipes are respectively inclined relative to the lower surface of the housing and an angle formed between each blowing pipe and the lower surface of the housing ranges from 30 degrees to 60 degrees.

Preferably, each blowing pipe has a blowing opening, a first guiding ring is disposed on an edge of the blowing opening; each vapor coating pipe has a coating opening, and a second guiding ring is disposed on the edge of the coating opening.

Preferably, the repairing device further includes a vapor coating device communicating with the vapor coating pipes, a blowing device communicating with the blowing pipes, a suction pipe communicating with the suction pipe, and a controller connected to the vapor coating device, the blowing device, and the suction device for respectively controlling the vapor coating device, the blowing device, and the suction device.

Preferably, the angle formed between the blowing pipe and the lower surface of the housing is 45 degrees.

With the configurations of the blowing pipes, the suction pipe, and the vapor coating pipes, the inert gas blown from the blowing pipes spreads from outside to inside, thus, molecules of the coating material ejected from the vapor coating pipes can be drawn close to the disconnected portion of the disconnected line, which avoids the short circuit caused by the spread molecules of the coating material in the present coating technology and increases the success rate of the coating operation.

### DESCRIPTION OF THE DRAWINGS

Many aspects of the embodiments can be better understood with reference to the following drawings. The components in the drawings are not necessarily dawns to scale, the emphasis instead being placed upon clearly illustrating the principles of the embodiments. Moreover, in the drawings, like reference numerals designate corresponding parts throughout the several views.

FIG. 1 is a schematic view showing the process of coating the disconnected line by a laser repairing device;

FIG. 2 is a schematic view showing the short circuit caused by the increased coating area formed by the repairing device;

FIG. 3 is a schematic view of a repairing device for repairing disconnected lines in accordance with a first embodiment of the present disclosure;

FIG. 4 is a schematic view of a disconnected portion after being coated by the repairing device of FIG. 3;

FIG. 5 is a front view of the repairing device of FIG. 3;

FIG. 6 is a bottom view of the repairing device of FIG. 3;

FIG. 7 is a schematic view of a repairing device for repairing disconnected lines in accordance with a second embodiment of the present disclosure;

FIG. 8 is a schematic view of a repairing device for repairing disconnected lines in accordance with a third embodiment of the present disclosure;

FIG. 9 is a bottom view of the repairing device of FIG. 8;

FIG. 10 is a cross-sectional view of the repairing device of FIG. 9 taken along the line A-A.

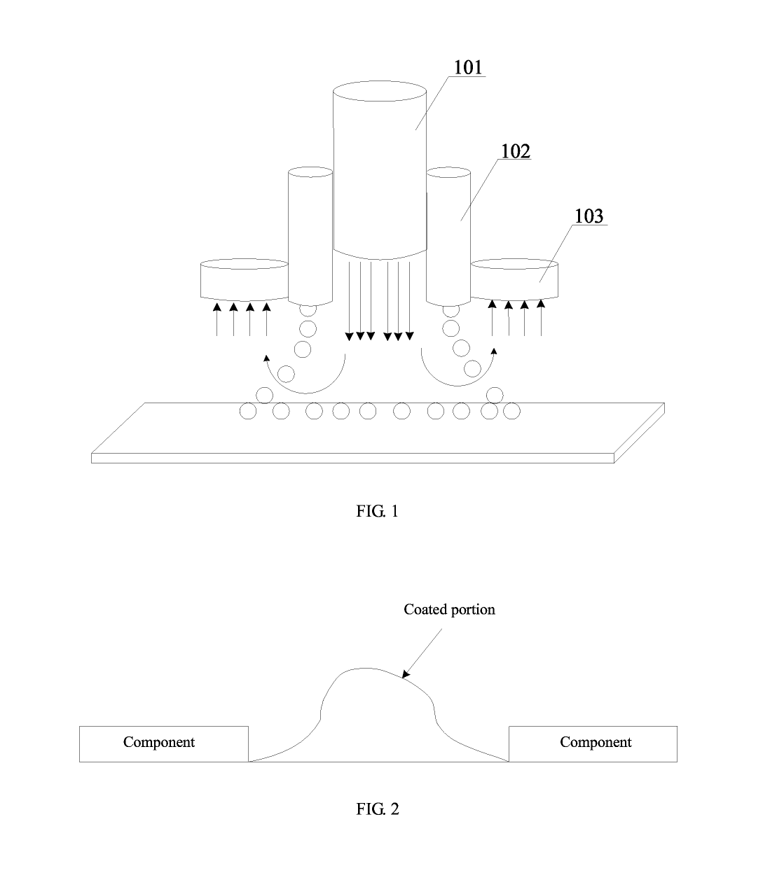

### DETAILED DESCRIPTION

The disclosure is illustrated by way of example and not by way of limitation in the figures of the accompanying drawings in which like references indicate similar elements. It should be noted that references to “an” or “one” embodiment is this disclosure are not necessarily to the same embodiment, and such references mean at least one.

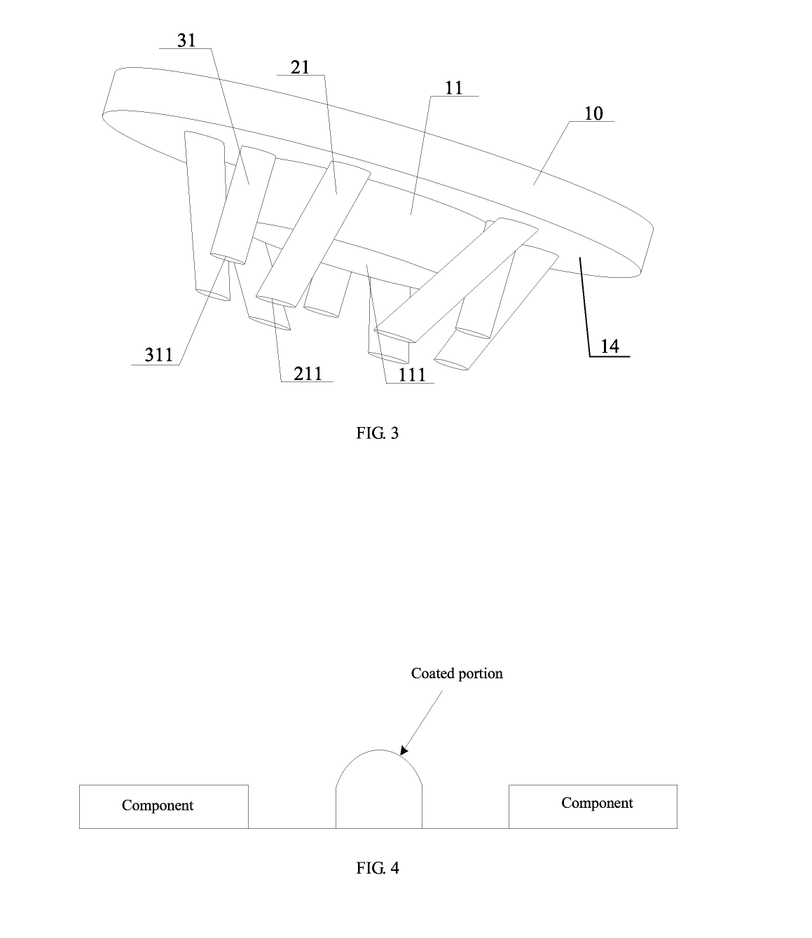

Referring to FIG. 3, which is a schematically view of a repairing device for repairing disconnected lines in accordance with a first embodiment of the present disclosure. The repairing device is placed above an array substrate for coating and repairing lines to connect the ends of the disconnected lines on the array substrate. The repairing device includes a housing 10 having a lower surface 14. A suction pipe 11 and a number of blowing pipes 21 surrounding the suction pipe 11 are disposed on the lower surface 14 of the housing 10. Each blowing pipe 21 is inclined relative to the suction pipe 11 and is noncoplanar with the suction pipe 11. A number of vapor coating pipes 31 are disposed on the housing 10 and are located between the suction pipe 11 and the blowing pipes 21.

Since the blowing pipes 21 surround the suction pipe 11, the blowing pipe 21 is inclined relative to the suction pipe 21 and is noncoplanar with the suction pipe 21, and the vapor coating pipes 31 are located between the blowing pipes 21 and the suction pipe 11, therefore, while the vapor coating pipes 31 are ejecting coating material having a number of molecules, the blowing pipes 21 simultaneously blow inert gas towards the suction pipe 11, which draws the molecules of the coating material close to a disconnected portion of the disconnected line and thus stabilizes the coating operation, and the inert gas is sucked by the suction pipes 11. Referring to FIG. 4, the disconnected portion of the disconnected line coated by the repairing device is schematically shown. The coating material is precisely controlled and prevented from spreading to other components located nearby and causing the short circuit, which improves the success rate of the coating operation.

With the above structures of the blowing pipes 21, the suction pipe 11, and the vapor coating pipes 31, the inert gas blown from the blowing pipes 21 spreads from outside to inside, which draws the molecules of the coating material ejected from the vapor coating pipes 31 close to the disconnected portion of the disconnected line. This avoids short circuits caused by the spreading molecules of the coating material used in the present coating technology and improves the success rate of the coating operation.

Furthermore, the suction pipe 11 is perpendicular to the housing 10 and has a suction opening 111. Each blowing pipe 21 has a blowing opening 211 which is inclined towards the suction pipe 11. Each blowing pipe 21 and the surface of the housing form an angle within a range from 30 degrees to 60 degrees. Preferably, the angle formed therebetween is 45 degrees.

Specifically, referring to FIG. 5, which is a front view of the repairing device. Take the blowing pipe 21a as an example, the direction of the gas flow blown therefrom is shown as P1, the direction of the gas flow sucked into the suction pipe 11 is shown as P2; neither the direction P2 intersects with the direction P1, nor the direction P2 is parallel with the direction P1. That is, the direction P2 is noncoplanar with the direction P1. The blowing opening 211a of the blowing pipe 21a is inclined towards the suction pipe 11. The other blowing pipes 21 are configured referring to the blowing pipe 21a described above, which is not given in detail. The molecules of the coating material from the vapor coating pipe 31 spread along the direction P3, which is parallel with the direction P2 and opposite to the direction P2.

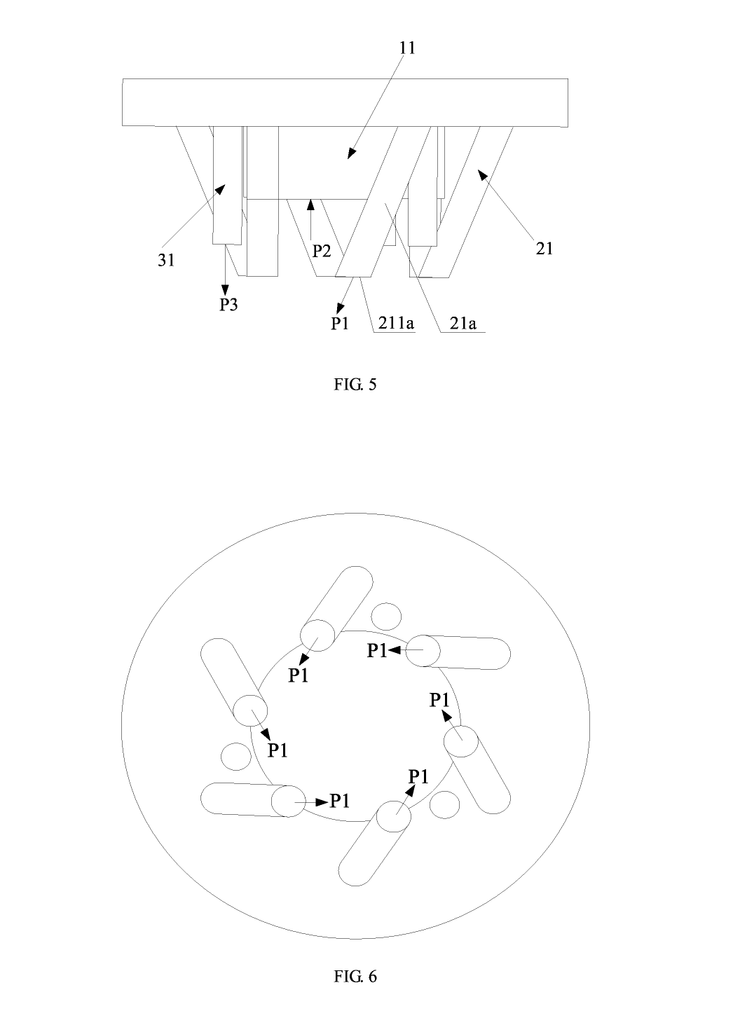

Referring to FIG. 6, which is a bottom view of the repairing device of FIG. 3. With the above configurations of the blowing pipes 21, the gas flow blown from the blowing openings 211 continuously whirls up counterclockwise to be sucked into the suction opening 111.

Referring to FIG. 7, a repairing device in accordance with a second embodiment is schematically shown. All the blowing pipes 21 of the repairing device of the second embodiment are also inclined relative to the housing 10, and the direction of the blowing pipes 21 relative to the housing 10 is symmetric to that of blowing pipes 21 relative to the housing 10 of the first embodiment about the radial direction of the housing 10. In this way, the gas flow blown from all the blowing pipes 21 can whirl clockwise.

Furthermore, the repairing device of the second embodiment further includes a vapor coating device, a blowing device, and a suction device (not shown in the drawings). The vapor coating device, the suction device, and the blowing device respectively communicates with the vapor coating pipes 31, the suction pipe 11, and the blowing pipes 21.

Specifically, the suction device and the blowing device can be disposed inside or outside the housing 10 and can be disposed independently. For example, the blowing device mainly includes a blower which is capable of rotating at high speed to blow the inert gas out from the blowing device through blowing pipes 21. The suction device includes a suction fan which is capable of rotating at high speed and lowering the air pressure in the suction pipe 11 to be lower than the atmosphere pressure, thereby sucking the gas from outside through the suction pipe 11.

It is understood that the suction device and the blowing device can be integrated into one device. For example, a channel may be formed extending from the suction device to the blowing device, thus, the inert gas can be sucked into the suction device through the suction pipe 11 and further be blown from the blowing device through the blowing pipe 21 via the blower thereof.

Furthermore, the repairing device further includes a controller connected to the vapor coating device, the blowing device, and the suction device for respectively controlling the vapor coating device, the blowing device, and the suction device.

Specifically, the controller is capable of controlling the vapor coating device and the blowing device to work simultaneously, and further controlling the suction device to work after a predetermined period. Thus, the suction device is capable of sucking the inert gas blown from the blowing pipe 21 through the suction opening 111 of the suction pipe 11 after the inert gas flow whirls upwards, thereby improving the efficiency of the repairing device.

Furthermore, the controller can also be connected to each blowing pipe 21 for controlling each blowing opening 211 of the blowing pipe 21 to move towards the suction pipe 11. Specifically, the controller controls each blowing opening 211 of the blowing pipe 21 to move towards the suction pipe 11 when controlling the blowing pipe 21 to blow the inert gas out. In this way, the inert gas blown from the blowing pipes 21 can gather around the suction pipe 11 and whirl up, allowing the suction pipe 11 to suck the inert gas more efficiently. Additionally, the controller can also control the blowing device, the vapor coating device, and the suction device to work in this order. With the controller, not only the success rate of the coating operation can be improved, but also the energy consumption is reduced.

Furthermore, each vapor coating pipe 21 has a coating opening 311. The distance between the coating opening 311 and the housing 10 is less than the distance between the blowing opening 211 and the housing 10 and greater than the distance between each suction opening 111 and the housing 10. Additionally, the area surrounded by the suction openings 211 is less than or equal to the area of the suction opening 111. After the repairing device is disposed above the array substrate, the inert gas blown from the blowing pipes 21 can be sucked into the suction pipe 11 with the above configurations of the suction pipe 21 and the blowing pipes 11, which improves the efficiency of the coating operation.

Furthermore, the repairing device includes even blowing pipes 21 which are symmetrically arranged about the suction pipe 11 and even vapor coating pipes 31 which are symmetrically arranged about the suction pipe 11.

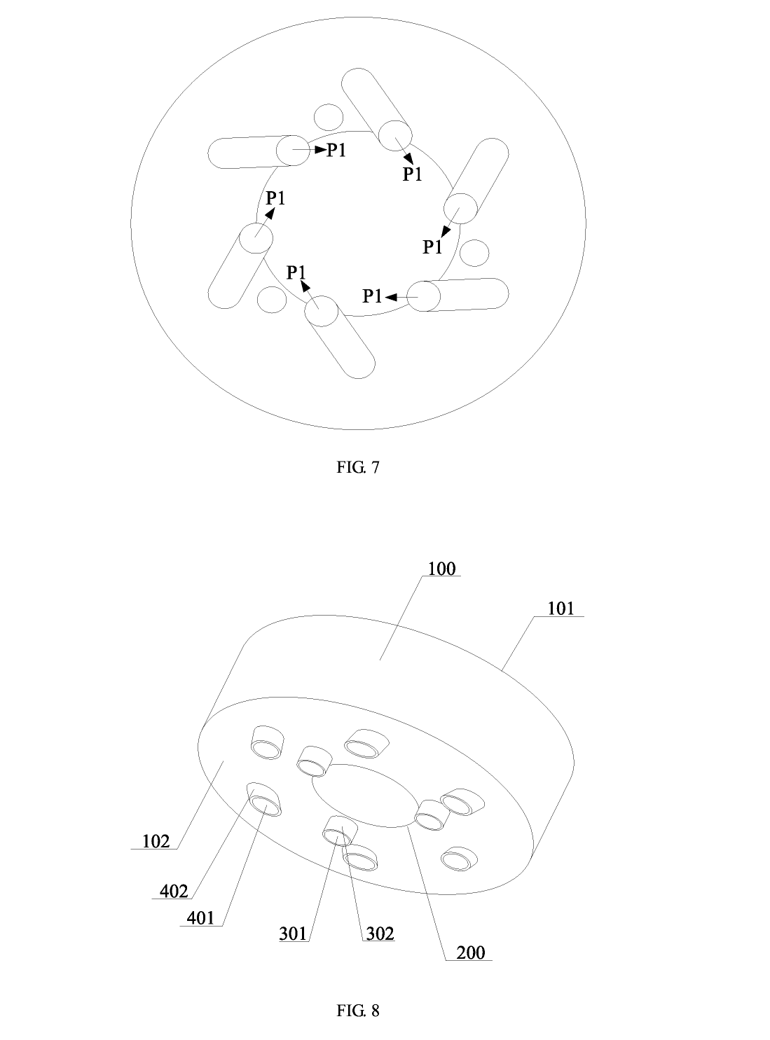

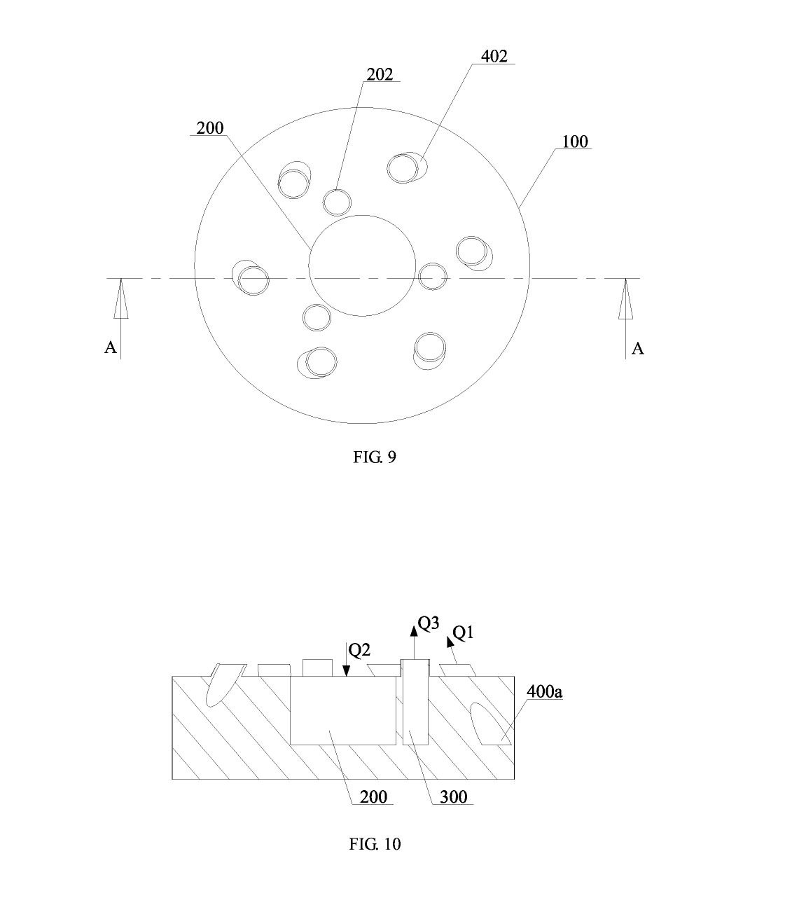

Referring to FIGS. 8 to 10, in which FIG. 8 is a schematic view of a repairing device of a third embodiment, FIG. 9 is a bottom view of the repairing device of the third embodiment, and FIG. 10 is a cross-sectional view of the repairing device taken along the line A-A. The repairing device of the third embodiment includes a cylindrical housing 100 having an upper surface 101 and a lower surface 102. A suction pipe 200 is disposed in a center portion of the housing 100 and runs through the lower surface 102 of the housing 100. A number of vapor coating pipes 300 parallel with the suction pipe 200 and surrounding the suction pipe 200 are also disposed in the housing 100. The vapor coating pipes 300 are surrounded by a number of blowing pipes 400 running through the lower surface 102.

The suction pipe 200 is perpendicular to the lower surface 102 of the housing 100. The suction pipe 200 includes a suction opening 201. Each blowing pipe 400 includes a blowing opening 401 inclined towards the suction pipe 200. The angle formed between each blowing pipe 400 and the lower surface of the housing 100 ranges from 30 degrees to 60 degrees. Preferably, the angle formed between each blowing pipe 400 and the lower surface of the housing 100 is 45 degrees.

Take a suction pipe 400a as an example, the direction of the gas flow blown from of the blowing pipe 400a is shown as Q1 and the direction of the gas flow sucked into the suction pipe 200 is shown as Q2. Neither the direction Q1 intersects with the direction Q2, nor the direction Q1 is parallel with the direction Q2. That is, the direction Q2 is noncoplanar with the direction Q1. Meanwhile, the blowing opening 401a of each blowing pipe 400a is inclined towards the suction pipe 200. The configurations of the other blowing pipes 400 are the same as that of the blowing pipe 400a, which is not given in detail. The molecules of the coating material ejected from the vapor coating pipe 300 spreads along the direction shown as Q3, which is parallel with and opposite to the direction Q2 of the gas flow sucked into the suction pipe 200.

In the above embodiment, the gas flow blown from the blowing opening 401 of the blowing pipes 400 whirls counter-clockwise. The gas flow continuously whirls up to be sucked into the suction opening 201 of the suction pipe 200. It is understood that if the inclined direction of the blowing pipes 400 relative to the housing 100 is symmetric to that of blowing pipes 400 relative to the housing 100 of the third embodiment about the radial direction of the housing 100, the gas flow blown from all the blowing pipes 400 will continuously whirl clockwise.

Furthermore, the repairing device of the third embodiment further includes a vapor coating device, a blowing device, and a suction device (not shown in the drawings). The vapor coating device, the suction device, and the blowing device respectively communicates with the vapor coating pipes 300, the suction pipe 200, and the blowing pipes 400.

Specifically, the suction device and the blowing device can be disposed inside or outside the housing 100 and can be disposed independently. For example, the blowing device mainly includes a blower capable of rotating at high speed to blow out the inert gas from the blowing device through the blowing pipes 400. The suction device includes a suction fan which is capable of rotating at high speed to lower the air pressure in the suction pipe 200 than the atmosphere pressure, thereby sucking the gas from outside through the suction pipe 200.

It is understood that the suction device and the blowing device can be integrated into one device. For example, a passageway of the suction device communicates with the passageway of the blowing device, thus, the inert gas can be sucked into the suction device through the suction pipe 200 and further blown out of blowing device from the blowing pipes 400 via the air blower thereof.

Furthermore, the repairing device further includes a controller connected to the vapor coating device, the blowing device, and the suction device for respectively controlling the vapor coating device, the blowing device, and the suction device.

Specifically, the controller is capable of controlling the vapor coating device and the blowing device to work simultaneously, and further controlling the suction device to work after a predetermined period. Thus, the suction device is capable of sucking the inert gas through the suction opening 201 of the suction pipe 200 blown from of the blowing pipe 400 more efficiently after the gas flow whirls upwards.

A first guiding ring 402 is disposed on an edge of the blowing opening 401 of each blowing pipe 400, and a second guiding ring 302 is disposed on the edge of the coating opening 301 of each vapor coating pipe 300. When the repairing device is at work, after the coating material ejected from the coating opening 301 passes through the second guiding ring 302 and the gas flow blown from of the blowing pipe 400 passes through the first guiding ring 402, the coating material is capable of gathering from outside to inside as the gas flow blows and being drawn close to the disconnected portion of the disconnected line to form the coated portion of the repaired line.

Furthermore, the repairing device includes even blowing pipes 400 which are symmetrically disposed about the suction pipe 200 and even vapor coating pipes 300 which are symmetrically disposed about the suction pipe 200.

Even though information and the advantages of the present embodiments have been set forth in the foregoing description, together with details of the mechanisms and functions of the present embodiments, the disclosure is illustrative only; and that changes may be made in detail, especially in matters of shape, size, and arrangement of parts within the principles of the present embodiments to the full extend indicated by the broad general meaning of the terms in which the appended claims are expressed.

What is claimed is:

1. A repairing device for repairing disconnected lines, comprising:
a suction pipe;
a plurality of blowing pipes surrounding the suction pipe and being noncoplanar with the suction pipe, each of the blowing pipes comprising a blowing opening inclined toward the suction pipe; and
a plurality of vapor coating pipes located between the suction pipe and being parallel with the suction pipe.

2. The repairing device as claimed in claim 1 further comprising a housing; the suction pipe, the blowing pipes, and the vapor coating pipes are all disposed on a lower surface of the housing, the suction pipe is perpendicular to the housing, and an angle formed between each blowing pipe and the lower surface of the housing ranges from 30 degrees to 60 degrees.

3. The repairing device as claimed in claim 2, wherein each vapor coating pipe has a coating opening, the suction pipe has a suction opening, a distance between the coating opening and the housing is less than a distance between the suction opening and the housing, but greater than a distance between the blowing opening and the housing.

4. The repairing device as claimed in claim 2, wherein the suction pipe has a suction opening, and an area surrounded by the blowing openings is less than or equal to the area of the suction opening.

5. The repairing device as claimed in claim 2 further comprising a controller connected to the blowing pipes for controlling the blowing openings of the blowing pipes to move towards the suction pipe.

6. The repairing device as claimed in claim 2, wherein the angle formed between each blowing pipe and the lower surface of the housing is 45 degrees.

7. The repairing device as claimed in claim 1 further comprising a housing, the housing has a lower surface, the suction pipe is disposed in a center portion of the housing and runs through the lower surface; the vapor coating pipes and the blowing pipes are disposed inside the housing and run through the lower surface, and an angle formed between the suction pipe and the lower surface ranges from 30 degrees to 60 degrees.

8. The repairing device as claimed in claim 7, wherein a first guiding ring is disposed on an edge of each blowing opening, each vapor coating pipe has a coating opening, and a second guiding ring is disposed on the edge of the coating opening.

9. The repairing device as claimed in claim 7, wherein the angle formed between each blowing pipe and the lower surface of the housing is 45 degrees.

10. A repairing device for repairing disconnected lines, comprising:
a suction pipe;
a plurality of blowing pipes surrounding the suction pipe, each of the blowing pipes being inclined relative to the suction pipe and being noncoplanar with the suction pipe; and
a plurality of vapor coating pipes located between the suction pipe and the blowing pipes.

11. The repairing device as claimed in claim 10 further comprising a housing, the suction pipe, the blowing pipes, and the vapor coating pipes are all disposed on a lower surface of the housing; the suction pipe is perpendicular to the housing, each blowing pipe has a blowing opening being inclined towards the suction pipe, and an angle formed between each blowing pipe and the lower surface of the housing ranges from 30 degrees to 60 degrees.

12. The repairing device as claimed in claim 11, wherein each vapor coating pipe comprises a coating opening, the suction pipe comprises a suction opening, a distance between each coating opening and the housing is greater than a distance between the suction opening and the housing, but less than a distance between each blowing opening and the housing.

13. The repairing device as claimed in claim 11, wherein the suction pipe comprises a suction opening, and an area surrounded by the blowing openings is less than an area of the suction opening.

14. The repairing device as claimed in claim 11 further comprising a controller connected to the blowing pipes for controlling the blowing openings of the blowing pipes to move towards the suction pipe.

15. The repairing device as claimed in claim 11, wherein the angle formed between each blowing pipe and the lower surface of the housing is 45 degrees.

16. The repairing device as claimed in claim 10 further comprising a housing having a lower surface, the suction pipe is disposed in a center portion of the housing and runs through the lower surface; the vapor coating pipes and the blowing pipes are disposed inside the housing and run through the lower surface of the housing; the blowing pipes are respectively inclined relative to the lower surface of the housing and an angle formed between each blowing pipe and the lower surface of the housing ranges from 30 degrees to 60 degrees.

17. The repairing device as claimed in claim 16, wherein each blowing pipe has a blowing opening, a first guiding ring is disposed on an edge of the blowing opening;
each vapor coating pipe has a coating opening, and a second guiding ring is disposed on the edge of the coating opening.

18. The repairing device as claimed in claim 16 further comprising a vapor coating device communicating with the vapor coating pipes, a blowing device communicating with the blowing pipes, a suction pipe communicating with the suction pipe, and a controller connected to the vapor coating device, the blowing device, and the suction device for respectively controlling the vapor coating device, the blowing device, and the suction device.

19. The repairing device as claimed in claim 16, wherein the angle formed between the blowing pipe and the lower surface of the housing is 45 degrees.
